(19) United States
(12) Patent Application Publication
(10) Pub. No.: US 2004/0209195 A1
(43) Pub. Date: Oct. 21, 2004

(54) Method for fabricating an interference display unit

(76) Inventor: Wen-Jian Lin, Hsinchu City (TW)

Correspondence Address: KNOBBE MARTENS OLSON & BEAR LLP, 2040 MAIN STREET, FOURTEENTH FLOOR, IRVINE, CA, 92614, US

(21) Appl. No.: 10/713,508

(22) Filed: Nov. 14, 2003

(30) Foreign Application Priority Data
Apr. 21, 2003 (TW) 92109265

(51) Int. Cl. G03F 7/20

(52) U.S. Cl. 430/315; 430/319; 430/321

(57) ABSTRACT

A method for fabricating an interference display unit is disclosed. A first wall and a sacrificial layer are formed in order on a substrate and an opening is formed in the first wall and the sacrificial layer. A first photoresist layer is spin-coated on the sacrificial layer and fills the openings. A post having a first arm is formed through patterning the first photoresist layer. At least a second photoresist is formed by spin-coating. A second arm is formed on the first arm through patterning the second photoresist layer. A second wall is formed on the sacrificial layer and posts. The first and the second arms' stress is released through a thermal process. The position of the arm is shifted and the distance between the first wall and the second wall is therefore defined. Finally, the sacrificial layer is removed.

### CLAIM OF PRIORITY

This application claims benefit to the Taiwanese Application No. 92109265 filed Apr. 21, 2003, which is hereby incorporated by reference herein.

### BACKGROUND OF THE INVENTION

1. Field of the Invention

The present invention relates to a method for manufacturing an optical interference display. More particularly, the present invention relates to a method for manufacturing an optical interference display with posts of arms.

2. Description of the Related Art

Planar displays are extremely popular in the portable and limited-space display market because they are lightweight and small. To date, planar displays including liquid crystal display (LCD), organic electro-luminescent display (OLED), plasma display panel (PDP) and so on, as well as a mode of the optical interference display have been investigated.

U.S. Pat. No. 5,835,255 discloses an array of display units of the visible light that can be used for a planar display. Reference is made to FIG. 1, which depicts a cross-sectional view of a display unit in the prior art. Every optical interference display unit 100 comprises two walls, 102 and 104. Posts 106 support these two walls 102 and 104, and a cavity 108 is subsequently formed. The distance between these two walls 102 and 104; that is, the length of the cavity 108 is D. One of the walls 102 and 104 is a semi-transmissible/semi-reflective layer with an absorption rate that partially absorbs visible light, and the other one is a light reflective layer that is deformable when a voltage is applied. When the incident light passes through the wall 102 or 104 and arrives in the cavity 108, in all the visible light spectrum, only visible light with a wavelength corresponding to formula 1.1 can generate a constructive interference and be emitted, that is,

2D=Nλ (1.1)

where N is a natural number.

When the length D of cavity 108 is equal to half of the wavelength times any natural number, a constructive interference is generated and a sharp light wave is emitted. In the mean time, if the observer follows the direction of the incident light, a reflected light with wavelength λ₁ can be observed. Therefore, the display unit 100 is “on”.

The first wall 102 is a semi-transmissible/semi-reflective electrode that comprises a substrate, an absorption layer, and a dielectric layer. An incident light passing through the first wall 102 is partially absorbed by the absorption layer. The substrate is made from conductive and transparent materials, such as ITO glass or IZO glass. The absorption layer is made from metal such as aluminum, chromium or silver and so on. The dielectric layer is made from silicon oxide, silicon nitrite or metal oxide. The metal oxide can be obtained by directly oxidizing a portion of the absorption layer. The second wall 104 is a deformable reflective electrode. It shifts up and down by applying a voltage. The second wall 104 is typically made from dielectric materials/conductive transparent materials, or metal/conductive transparent materials.

FIG. 2 depicts a cross-sectional view of a display unit in the prior art after applying a voltage. As shown in FIG. 2, while driven by the voltage, the wall 104 is deformed and falls down towards the wall 102 due to the attraction of static electricity. At this time, the distance between wall 102 and 104, that is, the length of the cavity 108, is not exactly zero, but is d, which can be zero. If d is used instead of D in formula 1.1, only visible light with a wavelength satisfying formula 1.1, which is λ₂, can generate a constructive interference, and be reflected by the wall 104, and pass through the wall 102. Due to the wall 102 with the high light absorption rate for the light with wavelength λ₂, all the incident light in the visible light spectrum is filtered out; therefore an observer who follows the direction of the incident light cannot observe any reflected light in the visible light spectrum. The display unit 100 is now “off”.

Reference is made to FIG. 1 again, which shows that the posts 106 of the display unit 100 are generally made from negative photoresist materials. Reference is also made to FIGS. 3A to 3C, which depict a method for manufacturing a display unit in the prior art. In FIG. 3A, the first wall 102 and a sacrificial layer 110 are formed in order on a transparent substrate 109, and then an opening 112 is formed in the wall 102 and the sacrificial layer 110. The opening 112 is suitable for forming posts therein. Next, a negative photoresist layer 111 is spin-coated on the sacrificial layer 110 and fills the opening 112. The objective of forming the negative photoresist layer 111 is to form posts between the first wall 102 and the second wall (not shown). A backside exposure process is performed on the negative photoresist layer 111 in the opening 112, in a direction indicated by arrow 113. The sacrificial layer 110 must be made from opaque materials, typically metal materials, to meet the requirements of the backside exposure process.

Reference is made to FIG. 3B, which shows that posts 106 remain in the opening 112 after removing the unexposed negative photoresist layer. The wall 104 is then formed on the sacrificial layer 110 and posts 106. Reference is made to FIG. 3C, in which the sacrificial layer 110 is removed by a release etch process to form a cavity 114. The length D of the cavity 114 is the thickness of the sacrificial layer 110. Therefore, the different thicknesses of the sacrificial layers must be used in different processes of the different display units to achieve the objective of controlling reflection of light with different wavelengths.

An array comprising the display unit 100 controlled by voltage operation is sufficient for a single color planar display, but not for a color planar display. A method in the prior art is to manufacture a pixel that comprises three display units with different lengths of the cavities as shown in FIG. 4, which depicts a cross-sectional view for a matrix color planar display in the prior art. Three display units 302, 304 and 306 are formed as an array on a substrate 300, respectively. Display units 302, 304 and 306 can reflect an incident light 308 to colors of light with different wavelengths, for example, which are red, green and blue lights, due to the different lengths of the cavities of the display units 302, 304 and 306. Use of different reflective mirrors for the display units arranged in the array is not required. More important is that good resolution is provided and the brightness among all colors of light is uniform. However, three display units with different lengths of cavities need to be manufactured separately.

Reference is made to FIGS. 5A to 5D, which depict cross-sectional views of a method for manufacturing the matrix color planar display in the prior art. In FIG. 5A, the first wall 310 and the first sacrificial layer 312 are formed in order on a transparent substrate 300, and then openings 314, 316, 318, and 320 are formed in the first wall 310 and the sacrificial layer 312 for defining predetermined positions wherein display units 302, 304, and 306 formed. Subsequently, the second sacrificial layer 322 is conformally formed on the first sacrificial layer 312 and in the openings 314, 316, 318, and 320.

In FIG. 5B, after the second sacrificial layer 322 in and between the openings 314 and 316, and in the openings 318 and 320 is removed by a photolithographic etch process, the third sacrificial layer 324 is conformally formed on the first sacrificial layer 312 and the second sacrificial layer 322 and in the openings 314, 316, 318 and 320.

Reference is made to FIG. 5C, in which the third sacrificial layer 324 in the openings 318 and 320 is left but the remainder of the third sacrificial layer 324 is removed by a photolithographic etching process. Next, a negative photoresist is spin-coated on the first sacrificial layer 312, the second sacrificial layer 322, and the third sacrificial layer 324, and in the openings 314, 316, 318 and 320, and fills the all openings to form a negative photoresist layer 326. The objective of the negative photoresist layer 326 is to form posts (not shown) between the first wall 310 and the second wall (not shown).

Reference is made to FIG. 5D, which shows that a backside exposure process is performed on the negative photoresist layer 326 in the openings 314, 316, 318 and 320, in a direction of the transparent substrate 300. For the requirement of the backside exposure process, the sacrificial layer 110 at least must be made from opaque materials, and typically metal materials. Posts 328 are left in the openings 314, 316, 318 and 320 after removing the unexposed negative photoresist layer 326. Subsequently, the second wall 330 conformally covers the first sacrificial layer 312, the second sacrificial layer 322, the third sacrificial layer 324 and posts 328.

Afterward, the first sacrificial layer 312, the second sacrificial layer 322, and the third sacrificial layer 324 are removed by a release etch process to form the display units 302, 304, and 306 shown in FIG. 4, where the lengths d1, d2, and d3 of three display units 302, 304, and 306 are the thicknesses of the first sacrificial layer 312, the second sacrificial layer 322, and the third sacrificial layer 324, respectively. Therefore, different thicknesses of the sacrificial layers must be used in different processes of the different display units to control reflection of different wavelengths of light.

At least three photolithographic etching processes are required for manufacturing the matrix color planar display in the prior art to define the lengths of the cavities of the display units 302, 304, and 306. In order to cooperate with the backside exposure for forming posts, metal materials must be used for making the sacrificial layer. The cost of the complicated manufacturing process is higher, and the yield cannot be raised due to the complicated manufacturing process.

Therefore, it is an important subject to provide a simple method of manufacturing an optical interference display unit structure, for manufacturing a color optical interference display with high resolution, high brightness, simple process and high yield.

### SUMMARY OF THE INVENTION

It is therefore an objective of the present invention to provide a method for manufacturing an optical interference display unit structure, which method is suitable for manufacturing a color optical interference display and provides high resolution and high brightness.

It is another objective of the present invention to provide a method for manufacturing an optical interference display unit structure suitable for manufacturing a color optical interference display, which method has a simple and easy manufacturing process and high yield.

It is still another objective of the present invention to provide a method for manufacturing an optical interference display unit structure suitable for manufacturing a color optical interference display with posts.

In accordance with the foregoing objectives of the present invention, one preferred embodiment of the invention provides a method for manufacturing an optical interference display unit structure. The first wall and a sacrificial layer are formed in order on a transparent substrate, and then an opening is formed in the first wall and the sacrificial layer. The opening is suitable for forming posts therein. Next, the first photoresist layer is spin-coated on the sacrificial layer and fills the opening. A photolithographic process patterns the photoresist layer to define a support with an arm, in which the support and the arm are used for a post, and to define the length of the first supporting layer. Subsequently, at least a second photoresist layer is spin-coated on the first photoresist layer and the sacrificial layer for defining the second supporting layer, in which the first and second supporting layers form an arm. Due to the exposure of the photoresist layer with the help of a mask, the sacrificial layer no longer must be made of opaque materials such as metal and the like; common dielectric materials are also used for making the sacrificial layer.

The second wall is formed on the sacrificial layer and posts, and then the posts are baked. The arm may generate displacement as the pivot of the support caused by stress action, in which an end of the arm adjacent to the support has less displacement, but another end of the arm has more displacement. The displacement of the arm may change the position of the second wall. Afterward, the sacrificial layer is removed by a release etch process to form a cavity, and the length D of the cavity may not be equal to the thickness of the sacrificial layer due to the displacement of the arm.

The arms with the ratios of various lengths to thicknesses have various amounts of stress due to the difference between thicknesses of arms, and displacements and directions generated by arms are variable during baking. Therefore, the arms with the ratios of various lengths to thicknesses may be used for controlling the length of the cavity, instead of the various thicknesses of the sacrificial layers used in the various processes of the display units to control various wavelengths of light reflected in the prior art. There are many advantages in the above way. First of all, the cost drops drastically. The thickness of the cavity in the prior art is the thickness of the sacrificial layer, and the sacrificial layer needs to be removed at the end of the process. However, the length of the cavity is increased by using an upward displacement of the arms in the present invention, so that the length of the cavity is greater than the thickness of the sacrificial layer, even when the thickness of the sacrificial layer is substantially decreased while forming the same length of cavities. Therefore, the material used for manufacturing the sacrificial layer is substantially reduced. Second, the process time is shortened. The release etch process of the metal sacrificial layer in the prior art consumes lots of time, because the sacrificial layer is removed by an etching gas that must permeate into spaces between the posts. The present invention utilizes the mask for a front exposure, so the sacrificial layer may be made of transparent materials such as dielectric materials, instead of opaque materials such as metal and the like in the prior art. Besides, the thickness used by the sacrificial layer can be substantially reduced, so the time required for the release etch process can be also drastically decreased. Moreover, the use of dielectric materials also speeds up the release etch process, such that the time required for the release etch process is decreased. Third, the length of the arms may decrease the effective reflection area of the optical interference display unit. If the color optical interference display is formed only with posts having arms of various lengths, because the effective reflection areas of the optical interference display units are different, variation may occur in the intensity of the reflected light. Furthermore, if the posts are made from photoresist materials, the thickness of the photoresist layer that is generally formed by spin-coating is limited. After a thermal process and displacement, the structural strength for supporting the second wall may not be enough. Thus, the variation in the thickness of arms of posts changes the ratios of lengths to thicknesses of arms for changing the stress of arms. It makes the effective reflection areas of optical interference display units with different colors of light closer to each other, and also strengthens the structural strength of arms. After baking, various optical interference display units have various lengths of the cavities due to the displacement of arms, such that reflected light is changed with various wavelengths, such as red (R), green (G), and blue (B) lights, so as to obtain various colors of light.

In accordance with another an objective of the present invention, one preferred embodiment of the invention provides a method for manufacturing a matrix color planar display structure. Each matrix color planar display unit has three optical interference display units. The first wall and a sacrificial layer are formed in order on a transparent substrate, and then an opening is formed in the first wall and the sacrificial layer. The opening is suitable for forming posts therein, and posts are used for defining the first, the second, and the third optical interference display units. Next, the first photoresist layer is spin-coated on the sacrificial layer and fills the opening. A photolithographic process patterns the photoresist layer to define a support with the first supporting layer. The support with the first supporting layer is used for a post, and defines the length of the arm. Then, the second photoresist layer is spin-coated on the first photoresist layer and the sacrificial layer and fills the opening. The second photoresist layer disposed on the first supporting layer of the second and the third optical interference display units is left for forming a second supporting layer by a photolithographic process. Later, the third photoresist layer is spin-coated on the first photoresist layer, the second photoresist layer, and the sacrificial layer and fills the opening. The third photoresist layer disposed on the second supporting layer of the third optical interference display unit, is left for forming a third supporting layer by a photolithographic process. The first supporting layer forms the first arm of the first optical interference display unit, the first and the second supporting layers form the second arm of the second optical interference display unit, and the first, the second and the third supporting layers form the third arm of the third optical interference display unit. The arms of three optical interference display units are the same in length but different in thickness. Due to the exposure of the photoresist layer with the help of a mask, the sacrificial layer no longer must be opaque materials such as metal and the like; common dielectric materials are also used for making the sacrificial layer.

The second wall is formed on the sacrificial layer and posts, and then the posts are baked. The arms of three optical interference display units are different in the ratio of length to thickness, and thus different in stress. After a thermal process, the arms of three optical interference display units are different in displacement. The arm may generate displacement as the pivot of the support caused by stress action, where an end of the arm adjacent to the support has less displacement, but another end of the arm has more displacement. The displacement of the arm may change the position of the second wall. Afterward, the sacrificial layer is removed by a release etch process to form a cavity, and the length D of the cavity may not be equal to the thickness of the sacrificial layer due to the displacement of the arm.

The first wall is the first electrode, and the second wall is the second electrode. Each arm of the optical interference display unit is different in length and stress. Therefore, after baking, each optical interference display unit has various lengths of the cavities due to the various displacements of arms, such that reflected light is changed with different wavelengths, such as red, green, and blue light, so as to obtain various colors of light, thus to obtain a matrix color planar display structure.

In accordance with the color planar display consisting of an array of optical interference display units disclosed by the present invention, high resolution and high brightness are obtained, and each optical interference display unit is similar in the effective reflection area, as well being simple in process and high in yield. It is understood that the present invention discloses the optical interference display unit which not only has uniform color tones, high resolution, high brightness, a simple process and high yield during forming arrays, but also increases the abundance during processing and raises the yield of the optical interference color planar display.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will be more fully understood by reading the following detailed description of the preferred embodiment, with reference made to the accompanying drawings as follows:

FIG. 1 depicts a cross-sectional view of a display unit in the prior art;

FIG. 2 depicts a cross-sectional view of a display unit in the prior art after applying a voltage;

FIGS. 3A to 3C depict a method for manufacturing a display unit in the prior art;

FIG. 4 depicts a cross-sectional view of a matrix color planar display in the prior art;

FIGS. 5A to 5D depict cross-sectional views of a method of manufacturing a matrix color planar display in the prior art;

FIGS. 6A to 6C depict a method for manufacturing an optical interference display unit according to one preferred embodiment of this invention;

FIG. 6D depict a cross-sectional view of an optical interference display unit according to one preferred embodiment of this invention; and

FIGS. 7A to 7F depict a method of manufacturing a matrix color planar display structure according to the second preferred embodiment of this invention.

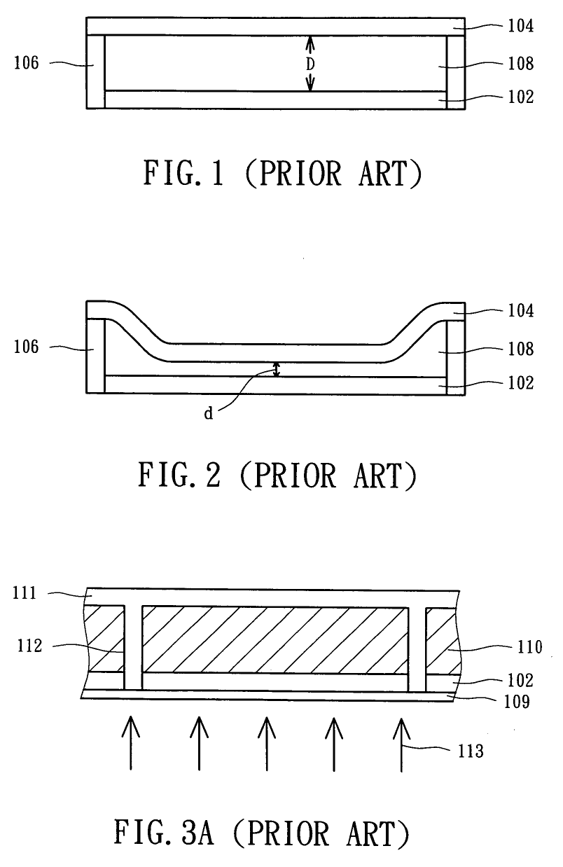

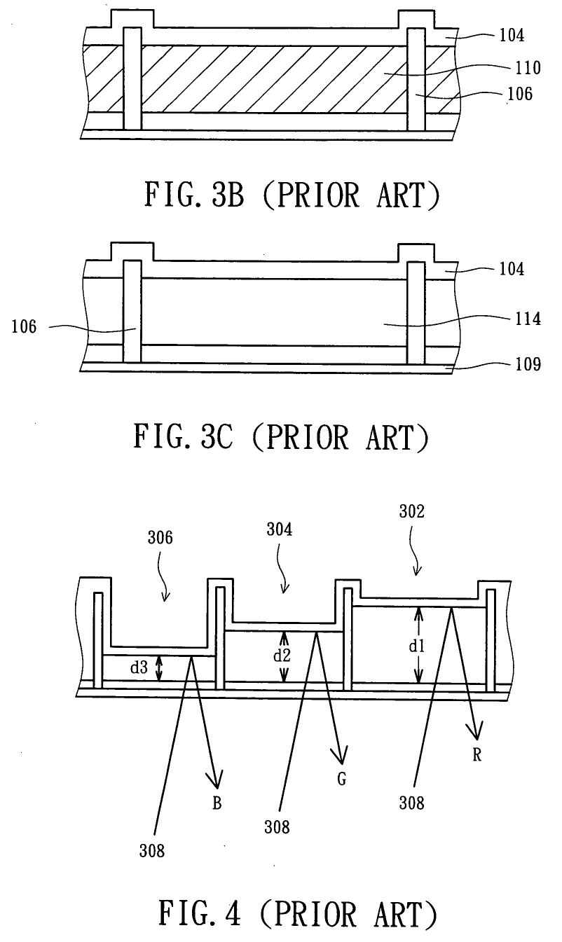

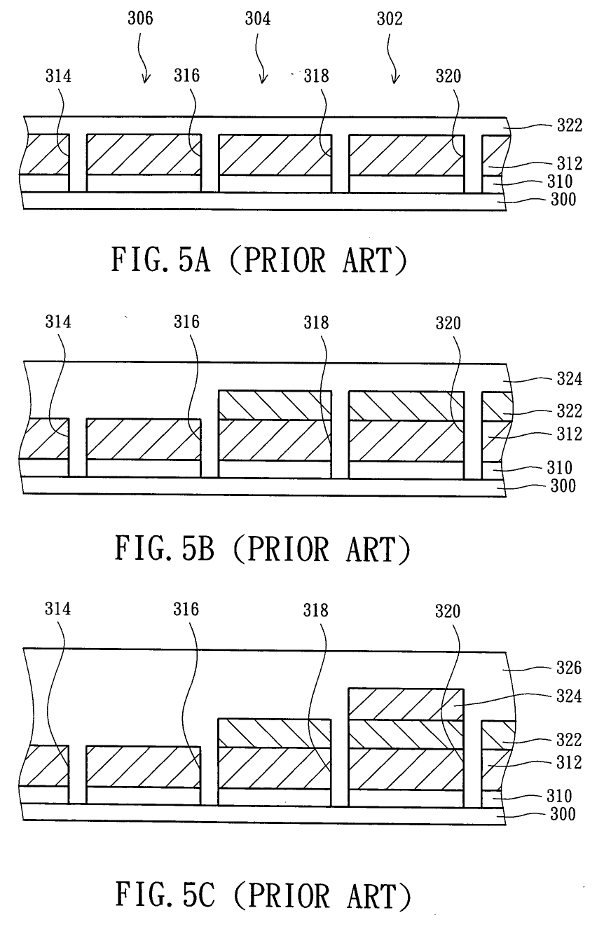

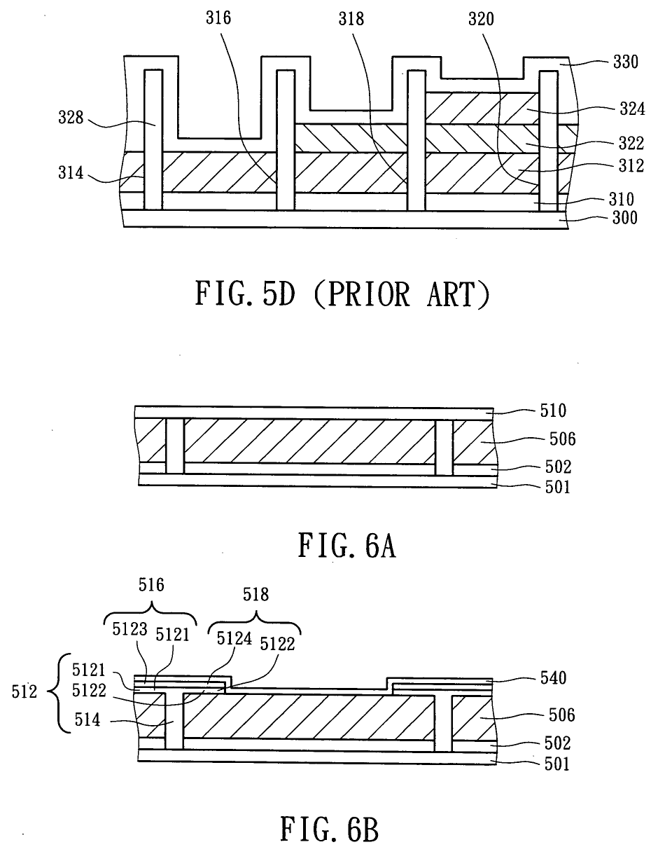

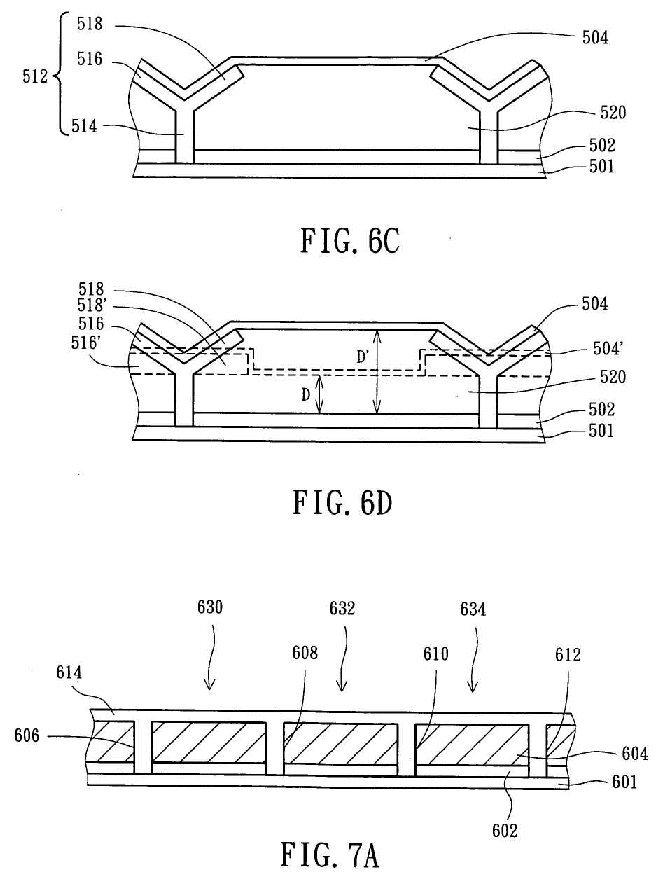

### DETAILED DESCRIPTION OF THE PREFERRED EMBODIMENT

In order to provide more information of the optical interference display unit structure, the first embodiment is provided herein to explain the optical interference display unit structure in this invention. In addition, the second embodiment is provided to give further description of the optical interference color planar display formed with an array of the optical interference display unit.

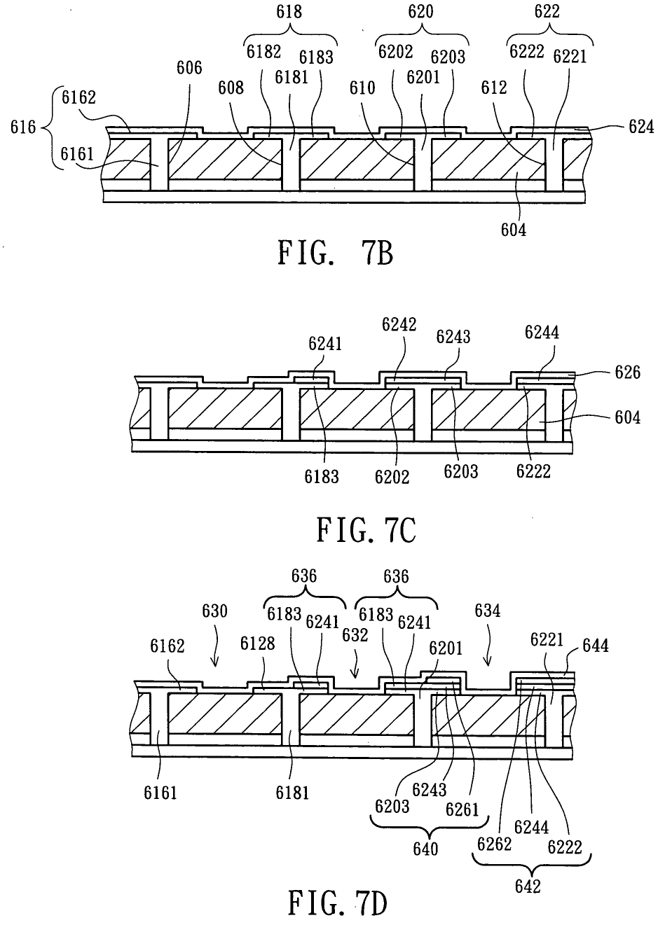

FIGS. 6A to 6C depict one embodiment of a method for manufacturing an optical interference display unit according to a preferred embodiment of the invention. Reference is made to FIG. 6A first, in which a first electrode 502 and a sacrificial layer 506 are formed in order on a transparent substrate 501. The sacrificial layer 506 may be made of transparent materials such as dielectric materials, or opaque materials such as metal materials. An opening 508 is formed in the first electrode 502 and the sacrificial layer 506 by a photolithographic etch process. The opening 508 is suitable for forming a post therein.

Next, a first material layer 510 is formed in the sacrificial layer 506 and fills the opening 508. The first material layer 510 is suitable for forming posts, and the first material layer 510 generally uses photosensitive materials such as photoresists, or a non-photosensitive polymer materials such as polyester, polyamide or the like. If the non-photosensitive materials are used for forming the material layer 510, a photolithographic etch process is required to define posts in the first material layer 510. In this embodiment, the photosensitive materials are used for forming the first material layer 510, so merely a photolithographic etch process is required for patterning the first material layer 510.

Reference is made to FIG. 6B, in which the posts 512 are defined by patterning the first material layer 510 during a photolithographic process. The post 512 has a support 514 disposed in the opening 508, and the post 512 has the first supporting layers 5121 and 5122. The same photolithographic process also defines the lengths of the first supporting layers 5121 and 5122. Next, a second material layer (not shown) is formed on the sacrificial layer 506 and the first supporting layers 5121 and 5122. Then, the second material layer on the sacrificial layer 506 is patterned and removed by a photolithographic process, for forming the second supporting layers 5123 and 5124 on the first supporting layers 5121 and 5122. Thus, the first supporting layer 5121 and the second supporting layer 5123 form the first arm 516, and the first supporting layer 5122 and the second supporting layer 5124 form the first arm 518. A second electrode 504 is formed on the sacrificial layer 506 and the post 512.

Reference is next made to FIG. 6C. A thermal process, such as baking, is performed. The first arm 516 and the second arm 518 of the post 512 may generate displacement as the pivot of the support 514 caused by stress action, where ends of the first arm 516 and the second arm 518 adjacent to the support 514 have less displacement, but another ends of the first arm 516 and the second arm 518 have more displacement. The displacement of the first arm 516 and the second arm 518 may change the position of the second electrode 504. Thereafter, the sacrificial layer 506 is removed by a release etching process to form a cavity 520.

If the first material layer 510 is made from photoresist materials, the spin-coated photoresist layer is limited in thickness; thus the first supporting layers 5121 and 5122 may have less structural strength. By forming the second supporting layers 5123 and 5124, the first supporting layers 5121 and 5122 are increased in thickness to strengthen their structural strength.

The optical interference display unit made as illustrated by FIGS. 6A to 6C is shown in FIG. 6D, which depicts a cross-sectional view of an optical interference display unit of one preferred embodiment of this invention. An optical interference display unit 500, which may be a color changeable pixel unit, at least comprises a first electrode 502 and a second electrode 504, with the first electrode 502 and the second electrode 504 are arranged approximately parallel to each other. The first electrode 502 and the second electrode 504 can be narrowband mirrors, broadband mirrors, non-metal mirrors or the combination thereof.

Posts 512 support the first electrode 502 and the second electrode 504. The first arm 516 and the second arm 518 of the posts 512 are raised upwards. The length of the cavity is the thickness of the sacrificial layer in the optical interference display unit structure in the prior art. If the thickness of the sacrificial layer is D, the length of the cavity is D, too. In this embodiment, a cavity 520 is formed between the first electrode 502 and the second electrode 504 supported by posts 512. The posts 512 have the first arm 516 and the second arm 518. The ratio of lengths to thicknesses of the first arm 516 and the second arm 518 decide stress thereof, and a dotted line 516′ and a dotted line 518′ label the positions prior to performing a thermal process of the first arm 516 and the second arm 518. After performing the thermal process, the first arm 516 and the second arm 518 may generate displacement; therefore the position of the second electrode 504 changes from the original position labeled by the dotted line 504′, and the length D′ of the cavity 520 between the first electrode 502 and the second electrode 504 changes from the original length D. Since the length of the cavity 520 is changed, the frequency of a reflected light changes following the length of the cavity 520. In general, when post 512 is made from polyamide compounds, the ratio of lengths to thicknesses of the first arm 516 and the second arm 518 is 5 to 50, and the length D′ of the cavity 520 is approximately 1.5 to 3 times the length D of the thickness of the sacrificial layer. Of course, the ratio of lengths to thicknesses of the first arm 516 and the second arm 518 can be changed to make the length D′ of the baked cavity 520 smaller than the thickness of the sacrificial layer.

In one aspect of this invention, the materials suitable for forming posts 512 include positive photoresists, negative photoresists, and all kinds of polymers such as acrylic resins and epoxy resins.

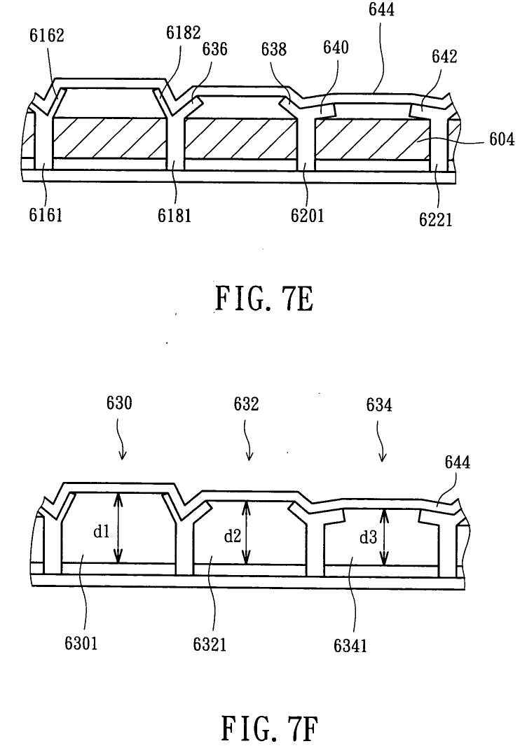

FIGS. 7A to 7F depict another embodiment of a method for manufacturing a matrix color planar display structure according to the second preferred embodiment of this invention. Reference is first made to FIG. 7A, in which the first electrode 602 and a sacrificial layer 604 are formed in order on a transparent substrate 601. The sacrificial layer 604 can be made of transparent materials such as dielectric materials, or opaque materials such as metal materials. Openings 606, 608, 610, and 612 are formed in the first electrode 602 and the sacrificial layer 604 by a photolithographic etch process, and openings 606, 608, 610, and 612 are suitable for forming posts therein.

Next, a material layer 614 is formed on the sacrificial layer 604 and fills the openings 606, 608, 610, and 612. The optical interference display unit 630 is defined by openings 606 and 608, the optical interference display unit 632 is defined by openings 608 and 610, and the optical interference display unit 634 is defined by openings 610 and 612. The material layer 614 is suitable for forming posts, and is generally made from photosensitive materials such as photoresists or a non-photosensitive polymer materials such as polyester, polyamide or the like. If non-photosensitive materials are used for forming the first material layer 614, a photolithographic etch process is required to define posts on the first material layer 614. In this embodiment, the photosensitive materials are used for forming the first material layer 614, so merely a photolithographic etch process is required for patterning the first material layer 614.

Reference is made to FIG. 7B. A photolithographic process patterns the first material layer 614, so as to define posts 616, 618, 620, and 622. The posts 616, 618, 620, and 622 have supports 6161, 6181, 6201, and 6221 disposed in the openings 606, 608, 610, and 612, respectively. The posts 616, 618, 620, and 622 also have the first supporting layers 6162, 6182, 6183, 6202, 6203, and 6222. The first supporting layers 6162, 6182, 6183, 6202, 6203, and 6222 are the same in length. Subsequently, a second material layer 624 is formed on the sacrificial layer 604 and the first supporting layers 6162, 6182, 6183, 6202, 6203, and 6222.

Reference is made to FIG. 7C. A photolithographic process patterns the second material layer 624, for keeping the second material layer 624 on the first supporting layers 6162, 6182, 6183, 6202, 6203, and 6222, so as to form the second supporting layers 6241, 6242, 6243, and 6244. Further, a third material layer 626 is formed on the sacrificial layer 604 and the second supporting layers 6241, 6242, 6243, and 6244.

Reference is made to FIG. 7D. A photolithographic process patterns the third material layer 626, for keeping the third material layer 626 on the second supporting layers 6241, 6242, 6243, and 6244, so as to form the third supporting layers 6261 and 6262. The first supporting layers 6162 and 6182 form the arms 646 and 648 of the optical interference display unit 630. The first supporting layers 6183 and 6202, and the second supporting layers 6241 and 6242 respectively, form the arms 636 and 638 of the optical interference display unit 632. The first supporting layers 6203 and 6222, the second supporting layers 6243 and 6244, and the third supporting layers 6261 and 6262 respectively, form the arms 640 and 642 of the optical interference display unit 634. Next, a second electrode 644 is formed on the sacrificial layer 604 and the arms 646, 648, 636, 638, 640, and 642.

Reference is made to FIG. 7E. A thermal process, such as baking, is performed. The arms 646, 648, 636, 638, 640, and 642 of the optical interference display units 630, 632, and 634 may generate displacement as the pivot of the supports 6161, 6181, 6201, and 6221 caused by stress action. There is less displacement at the ends of the arms 646, 648, 636, 638, 640, and 642 adjacent to the supports 6161, 6181, 6201, and 6221, but more displacement at the other ends of the arms 646, 648, 636, 638, 640, and 642. The displacements of the arms 646 and 648 are the same, the displacements of the arms 636 and 638 are the same, and the displacements of the arms 640 and 642 are the same. But there are various displacements among three above pairs of the arms. Therefore, the amount of change in positions of the second electrode 644 caused by the arms 646 and 648, the arms 636 and 638, and the arms 640 and 642 is also varied.

Thereafter, reference is made to FIG. 7F. The sacrificial layer 604 is removed by a release etch process to form the cavities 6301, 6321, and 6341 of the optical interference display units 630, 632, and 634. The cavities 6301, 6321, and 6341 have various lengths d₁, d₂, and d₃, respectively. In the state that the optical interference display units 630, 632, and 634 are “on”, as shown as the formula 1.1, the design of lengths d₁, d₂, and d₃ of the cavities 6301, 6321, and 6341 can generate the reflected light with different wavelengths, such as red (R), green (G), or blue (B) light.

The lengths d₁, d₂, and d₃ of the cavities 6301, 6321, and 6341 are not decided by the thickness of the sacrificial layer, but by the lengths of the arms 646 and 648, 636 and 638, and 640 and 642, respectively. Therefore, a complicated photolithographic process as seen in the prior art where various lengths of the cavities are defined by forming various thicknesses of the sacrificial layers is unnecessary.

Although the present invention has been described in considerable detail with reference certain preferred embodiments thereof, other embodiments are possible. Therefore, their spirit and scope of the appended claims should no be limited to the description of the preferred embodiments container herein. In view of the foregoing, it is intended that the present invention cover modifications and variations of this invention provided they fall within the scope of the following claims and their equivalents.

What is claimed is:

1. A method for manufacturing an optical interference display unit disposed on a substrate, the method comprising:
forming a first electrode on the substrate;
forming a sacrificial layer on the first electrode;
forming at least two openings in the sacrificial layer and the first electrode to define a position of the optical interference display unit;
forming a first photosensitive material layer to fill the openings and cover the sacrificial layer;
patterning the first photosensitive material layer to form a support in each of the openings and at least one first supporting layer on the support, wherein the support and the at least one first supporting layer form a post;
forming at least one second photosensitive material layer on the sacrificial layer and the at least one first supporting layer;
patterning the at least one second photosensitive material layer to form a second supporting layer on the at least one first supporting layer, wherein the at least one first supporting layer and the second supporting layer form an arm;
forming a second electrode on the sacrificial layer and the arm;
performing a thermal process; and
removing the sacrificial layer.

2. The method for manufacturing an optical interference display unit of claim 1, wherein the first photosensitive material layer and the second photosensitive material layer are a photoresist layer.

3. The method for manufacturing an optical interference display unit of claim 1, wherein the step of patterning the first photosensitive material layer and the second photosensitive material layer includes a photolithographic process.

4. The method for manufacturing an optical interference display unit of claim 1, wherein the thermal process is baking.

5. The method for manufacturing an optical interference display unit of claim 1, wherein the thermal process makes the arm generate displacement due to stress.

6. The method for manufacturing an optical interference display unit of claim 1, wherein the second electrode is a deformable electrode.

7. The method for manufacturing an optical interference display unit of claim 1, wherein the second electrode is a movable electrode.

8. The method for manufacturing an optical interference display unit of claim 1, wherein the post is made from photoresist.

9. A method for manufacturing a matrix color optical interference display unit disposed on a substrate, the method comprising:
forming a first electrode on the substrate;
forming a sacrificial layer on the first electrode;
forming at least four openings in the sacrificial layer and the first electrode to define positions of a first optical interference display unit, a second optical interference display unit, and a third optical interference display unit;
forming a support in each of the openings and at least one first supporting layer on the support, wherein the at least one first supporting layer forms a first arm;
forming at least one second supporting layer on the at least one first supporting layer of the second optical interference display unit and the third optical interference display unit, wherein the at least one first supporting layer and the at least one second supporting layer form a second arm;
forming at least one third supporting layer on the at least one second supporting layer of the third optical interference display unit to increase the thickness thereof, wherein the at least one first supporting layer, the at least one second supporting layer, and the at least one third supporting layer form a third arm;
forming a second electrode on the sacrificial layer and the first arm, the second arm, and the third arm;
performing a thermal process; and
removing the sacrificial layer.

10. The method for manufacturing a matrix color optical interference display unit of claim 9, wherein the support and the first arm, the support and the second arm, and the support and the third arm form posts.

11. The method for manufacturing a matrix color optical interference display unit of claim 10, wherein a material for forming the posts is selected from a group consisting of photosensitive materials, non-photosensitive materials and a combination thereof.

12. The method for manufacturing a matrix color optical interference display unit of claim 11, wherein the photosensitive materials are a photoresist.

13. The method for manufacturing a matrix color optical interference display unit of claim 9, wherein the step of forming the support and the at least one first supporting layer comprises:
forming a first photosensitive material layer to fill the openings and cover the sacrificial layer; and
patterning the first photosensitive material layer to form the support in each of the openings and the at least one first supporting layer on the support.

14. The method for manufacturing a matrix color optical interference display unit of claim 13, wherein the step of patterning the first photosensitive material layer includes a photolithographic process.

15. The method for manufacturing a matrix color optical interference display unit of claim 9, wherein the step of forming the support and the at least one first supporting layer further comprises:
forming a first non-photosensitive material layer to fill the openings and cover the sacrificial layer; and
patterning the first non-photosensitive material layer to form the support in each of the openings and the first arm on the support by a photolithographic etch process, wherein the support and the at least one arm are formed the post.

16. The method for manufacturing a matrix color optical interference display unit of claim 9, wherein the thermal process is baking.

17. The method for manufacturing a matrix color optical interference display unit of claim 9, wherein the thermal process makes the first arm, the second arms, and the third arm to generate displacement due to stress.

18. The method for manufacturing a matrix color optical interference display unit of claim 9, wherein the second electrode is a deformable electrode.

19. The method for manufacturing a matrix color optical interference display unit of claim 9, wherein the second electrode is a movable electrode.
